(19) United States
(12) Patent Application Publication
(10) Pub. No.: US 2025/0385274 A1
(43) Pub. Date: Dec. 18, 2025

(54) METHODS AND COMPOSITIONS FOR NANOSCALE SURFACE COATINGS FOR ENHANCING DURABILITY AND PERFORMANCE OF SOLID OXIDE CELLS

(71) Applicant: West Virginia University Board of Governors on Behalf of West Virginia University, Morgantown, WV (US)

(72) Inventors: Xueyan Song, Morgantown, WV (US); Yun Chen, Morgantown, WV (US); Cesar-Octavio Romo-De-La-Cruz, Morgantown, WV (US)

(21) Appl. No.: 18/856,348

(22) PCT Filed: Apr. 13, 2023
(86) PCT No.: PCT/US2023/018546

§ 371 Date: Oct. 11, 2024

Related U.S. Application Data
(60) Provisional application No. 63/330,519, filed on Apr. 13, 2022.

(51) Int. Cl. H01M 4/90; H01M 4/88; H01M 8/12; H01M 8/1213

(52) U.S. Cl. CPC H01M 4/9033; H01M 4/8867; H01M 8/1213; H01M 2008/1293

(57) ABSTRACT

In one aspect, the disclosure relates to SOC cells comprising a conformal nanolayer comprising PrOₓ on an oxygen electrode backbone, e.g., an LSM oxygen electrode. The disclosed SOC cells comprising a conformal nanolayer comprising PrOₓ on an oxygen electrode backbone are prepared using a disclosed Atomic Layer Deposition (ALD) coating method. The SOC cells comprising a conformal nanolayer comprising PrOₓ on an oxygen electrode backbone can further comprise an additional layer material, e.g., MnOₓ and/or CoOₓ, thereon or therein the conformal nanolayer comprising PrOₓ. The performance of the disclosed SOC cells is improved compared to baseline cells lacking the disclosed ALD coating on an oxygen electrode backbone, e.g., an LSM oxygen electrode. This abstract is intended as a scanning tool for purposes of searching in the particular art and is not intended to be limiting of the present disclosure.

### CROSS-REFERENCE TO RELATED APPLICATIONS

This application claims the benefit of U.S. Provisional Application No. 63/330,519, filed on Apr. 13, 2022, which is incorporated herein by reference in its entirety.

### STATEMENT REGARDING FEDERALLY SPONSORED RESEARCH

This disclosure was made with U.S. Government support under grant numbers DE-FE0031665 and DE-FE0032112, awarded by the Department of Energy, and grant number NSF-DMR 1916581, awarded by the National Science Foundation. The U.S. government has certain rights in the disclosure.

### BACKGROUND

Solid Oxide Cells (SOCs) can operate as solid oxide fuel cells (SOFCs) by oxidizing a fuel to produce electricity and as solid oxide electrolysis cells (SOECs) by electrolyzing water to produce hydrogen and oxygen gases. While the production of hydrogen is urgently pursued worldwide, the SOEC systems are practically adapting the well-developed SOFC systems to shorten the development of SOEC devices. Operation of the SOEC stacks at higher current densities over 0.75 A/cm² and a low degradation rate of less than 0.5%/1000 h could enable cost-competitive production of synthetic hydrocarbon fuels without consuming fossil fuels (Ref. 1). However, SOEC usually presents low current density (correspond to low hydrogen production rate) and more severe degradation than SOFC, and the degradation of SOEC is strictly dependent on the electrolysis operation conditions, presenting accelerated degradation at higher current densities such as those over 0.75 A/cm². Most importantly, the SOEC degradation is rooted in both the fuel and oxygen electrodes and varies based on the cell structure of the electrode.

In terms of the oxygen electrode, a mixed electrical and ionic conducting lanthanum strontium cobalt ferrite (LSCF)/Samaria-Doped Ceria (SDC) electrode is a common choice for SOFC and SOEC operation at the operation temperature of ˜750° C. However, the LSCF experiences decomposition over the prolonged operation, and the resultant loss of the electrocatalytic activity, due to the cations Sr surface segregation (Ref. 2). At high temperatures over 850° C., lanthanum strontium manganite (LSM) based materials are the most popular choice for SOFC because of their high chemical and thermal compatibility with conventional yttria-stabilized zirconia (YSZ) electrolytes, adequate electrochemical performance, and superior stability upon long-term operation (Ref. 3). However, LSM possesses negligible ionic conductivity and low oxygen surface exchange, thus restricting the electrochemically active sites to limited triple phase boundary (TPBs). More severely, in the SOEC mode, the limited ionic conductivity from LSM resulted in the immediate build-up of oxygen at the electrolyte and oxygen electrode interface and resulted in catastrophic delamination and immediate failure of the entire cell (Ref. 4-5). Furthermore, the Cr vapor contamination evaporated from the metallic interconnect, and their reactions with Sr-containing perovskite are still a severe problem for both LSM and LSCF-based electrodes. The development of novel materials, or the improvement of existing ones is urgently needed for SOECs.

Despite advances in research directed to robust solid oxide cells, such as SOECs, capable of operating at elevated temperatures over an extended period of time, there remains a lack of suitable SOECs having electrodes with sufficient electrical and ionic conductivity with high catalytic activity under such conditions. These needs and other needs are satisfied by the present disclosure.

### SUMMARY

In accordance with the purpose(s) of the disclosure, as embodied and broadly described herein, the disclosure, in one aspect, relates to SOC cells comprising a conformal nanolayer comprising PrOₓ on an oxygen electrode backbone, e.g., an LSM oxygen electrode. In a further aspect, the disclosed SOC cells comprising a conformal nanolayer comprising PrOₓ on an oxygen electrode backbone, e.g., an LSM oxygen electrode, are prepared using a disclosed Atomic Layer Deposition (ALD) coating method. In a still further aspect, the disclosed SOC cells comprising a conformal nanolayer comprising PrOₓ on an oxygen electrode backbone, e.g., an LSM oxygen electrode, can further comprise an additional layer material, e.g., MnOₓ and/or CoOₓ, thereon or therein the conformal nanolayer comprising PrOₓ. In a yet further aspect, the performance of the disclosed SOC cells is improved compared to baseline cells lacking the disclosed ALD coating on an oxygen electrode backbone, e.g., an LSM oxygen electrode.

In further accordance with the purpose(s) of the disclosure, as embodied and broadly described herein, the disclosure, in one aspect, relates to further hydrogen production rate increase, operation voltage decrease, and the cell contaminants tolerance increase could be achieved by designing the ALD layers to be dual or multilayers. The PrOₓ containing ALD layer dual layers or multilayers could contain other oxides, but not limited to CeOₓ, MnOₓ, and CoOₓ. The number of layers, layer thickness, and layer chemistry are tunable. The PrOₓ containing ALD coating of single layer dual layers or multilayers are applicable and effective for both LSM and LSCF-based oxygen electrodes, regardless of the structure and composition of the fuel electrode of the entire SOEC.

Disclosed are electrodes comprising: an electrode and an electrode coating layer; wherein the electrode coating layer comprises a conformal nanolayer comprising a PrOₓ layer on the electrode.

Also disclosed are solid oxide cells comprising the disclosed electrodes.

Also disclosed are articles comprising the disclosed electrodes.

Also disclosed are methods of making the disclosed electrodes, the method comprising: providing a substrate an atomic layer deposition reaction chamber; performing at least one atomic layer deposition cycle to form an electrode coating layer on a surface of an electrode; wherein the electrode coating layer comprises PrOₓ; wherein the first coating layer is superjacent to the substrate.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described aspects are usable in all aspects of the disclosure taught herein. Furthermore, the individual features of the dependent claims, as well as all optional and preferred features and modifications of the described aspects are combinable and interchangeable with one another.

### BRIEF DESCRIPTION OF THE FIGURES

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A-1B show representative transmission electron microscopy (TEMs) images of disclosed atomic layer deposition (ALD) layers. FIG. 1A shows a TEM image of a disclosed atomic layer deposition layer. FIG. 1B shows a further TEM image of a disclosed atomic layer deposition layer. The foregoing images show deep penetration within the narrow gaps of porous electrodes of cells. These images show that the ALD layer is very uniform and conformal with subsequent formation of a conformal and stable nanostructure on the internal surface of the anode upon cell operation.

FIGS. 2A-2D show representative data for cell area-specific resistance (ASR); ohmic resistance, Rₛ; polarization resistance, Rₚ; and total resistance, Rₜ, as a function of temperature for a disclosed ALD-coated oxygen electrode in an LSM cell compared to the same LSM cell without a disclosed ALD-coated oxygen electrode. FIG. 2A shows representative data for ohmic resistance, Rₛ, for a disclosed ALD-coated oxygen electrode in an LSM cell compared to the same LSM cell without a disclosed ALD-coated oxygen electrode. FIG. 2B shows representative data for polarization resistance, Rₚ, for a disclosed ALD-coated oxygen electrode in an LSM cell compared to the same LSM cell without a disclosed ALD-coated oxygen electrode. FIG. 2C shows representative data for total resistance, Rₜ, for a disclosed ALD-coated oxygen electrode in an LSM cell compared to the same LSM cell without a disclosed ALD-coated oxygen electrode. FIG. 2D shows representative data for ASR for a disclosed ALD-coated oxygen electrode in an LSM cell compared to the same LSM cell without a disclosed ALD-coated oxygen electrode. In each of FIGS. 2A-2D, the absolute value of coated LSM cell and reduction (%) compared to uncoated LSM cell are shown as indicated.

FIG. 3 shows representative data for evolution of terminal voltage under SOFC and SOEC modes of operation. The peaks on the graph correspond to the timeframe when impedance and power density analyses were taken.

FIGS. 4A-4B show representative performance data for conventional oxygen electrodes compared to a disclosed ALD-coated oxygen electrode. FIG. 4A shows SOEC data presented for a conventional cell using a conventional oxygen electrode (left side of graph) compared to a cell comprising a disclosed ALD-coated oxygen electrode (right side of graph).

FIG. 4B shows the increase of the cell operation voltage, i.e., the degradation of the cells/stacks, for conventional cells comprising conventional oxygen electrodes.

FIG. 5 shows representative data for the evolution of terminal voltage for a disclosed cell comprising a disclosed ALD-coated oxygen electrode. In the data shown, an LSM cell was infiltrated with PrOₓ with a dip coating, and further coated with Mn and Co via atomic layer deposition (ALD) methods. The cell was operated at a constant current density of 0.3 A/cm² in SOFC mode under Cr contamination. The peaks on the graph corresponded to the timeframe when impedance and power density analysis was taken.

Additional advantages of the disclosure will be set forth in part in the description which follows, and in part will be obvious from the description, or can be learned by practice of the disclosure. The advantages of the disclosure will be realized and attained by means of the elements and combinations particularly pointed out in the appended claims. It is to be understood that both the foregoing general description and the following detailed description are exemplary and explanatory only and is not restrictive of the disclosure, as claimed.

### DETAILED DESCRIPTION

Many modifications and other aspects disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific aspects disclosed and that modifications and other aspects are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As will be apparent to those of skill in the art upon reading this disclosure, each of the individual aspects described and illustrated herein has discrete components and features which may be readily separated from or combined with the features of any of the other several aspects without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present disclosure is not entitled to antedate such publication by virtue of prior disclosure. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### A. DEFINITIONS

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used herein, the term “and/or” includes any and all combinations of one or more of the associated listed items. Expressions such as “at least one of,” when preceding a list of elements, modify the entire list of elements and do not modify the individual elements of the list.

As used herein, nomenclature for compounds, including organic compounds, can be given using common names, IUPAC, IUBMB, or CAS recommendations for nomenclature. When one or more stereochemical features are present, Cahn-Ingold-Prelog rules for stereochemistry can be employed to designate stereochemical priority, E/Z specification, and the like. One of skill in the art can readily ascertain the structure of a compound if given a name, either by systemic reduction of the compound structure using naming conventions, or by commercially available software, such as CHEMDRAW™ (Cambridgesoft Corporation, U.S.A.).

Reference to “a” chemical compound refers to one or more molecules of the chemical compound rather than being limited to a single molecule of the chemical compound. Furthermore, the one or more molecules may or may not be identical, so long as they fall under the category of the chemical compound. Thus, for example, “a” chemical compound is interpreted to include one or more molecules of the chemical, where the molecules may or may not be identical (e.g., different isotopic ratios, enantiomers, and the like).

As used in the specification and the appended claims, the singular forms “a,” “an” and “the” include plural referents unless the context clearly dictates otherwise. Thus, for example, reference to “an ALD-coated cell,” “a nanocomposite,” or “a nanoparticle,” includes, but is not limited to, two or more such ALD-coated cells, nanocomposites, or nanoparticles, and the like.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity and, thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter, or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, the term “effective amount” refers to an amount that is sufficient to achieve the desired modification of a physical property of the composition or material. For example, an “effective amount” of a nanocomposite layer refers to a nanocomposite layer that is sufficiently thick to achieve the desired improvement in the property modulated by the nanocomposite layer, e.g., conductivity and/or stability of the cell. The specific level in terms of thickness (nm) required as an effective amount will depend upon a variety of factors composition of the oxygen electrode, temperature parameters for use, and the like.

As used herein, “solid oxide fuel cell” or “SOFC” refers to an electrochemical conversion device that produces electricity by oxidizing a fuel. Generally speaking, a SOFC operates as follows: reduction of oxygen molecules into oxygen ions occurs at an oxygen electrode; an electrolyte material conducts the negative oxygen ions from the oxygen electrode to an anode, where electrochemical oxidation of oxygen ions with hydrogen or carbon monoxide occurs; the electrons then flow through an external circuit and re-enter the oxygen electrode.

As used herein, “solid oxide electrolysis cell” or “SOEC” refers to a solid oxide fuel cell that runs in regenerative mode to achieve the electrolysis of water by using a solid oxide electrolyte to produce hydrogen gas and oxygen.

As used herein, “electrode” includes electric conducting structures (including oxygen electrode and/or anode) suitable for electrochemical energy conversion devices, including solid oxide fuel cell (SOFC) and solid oxide electrolysis cell (SOEC) as well as a protonic conductor.

As used herein, “conformal coating” refers to a coating or layer which matches or follows the topography of the underlying substrate.

As used herein, “disclosed coated oxygen electrode” and “disclosed cell with PrOₓ coated oxygen electrode” can be used interchangeably and refer to a SOC cell comprising an oxygen electrode, e.g., an LSM oxygen electrode or an LCSF oxygen electrode.

As used herein, “disclosed LCSF with PrOₓ coated oxygen electrode”, “disclosed LCSF cell with PrOₓ coated oxygen electrode”, “disclosed cell with PrOₓ coated oxygen electrode”, “disclosed LCSF with coated oxygen electrode”, and “disclosed cell with coated oxygen electrode” can be used interchangeably and refer to a SOC cell comprising an LCSF electrode comprising an oxygen electrode comprising a PrOₓ coating, such that the PrOₓ coating is provided via ALD methods and/or dip coating methods.

As used herein, “disclosed LSM with PrOₓ coated oxygen electrode”, “disclosed LSM cell with PrOₓ coated oxygen electrode”, “disclosed cell with PrOₓ coated oxygen electrode”, “disclosed LSM with coated oxygen electrode”, and “disclosed cell with coated oxygen electrode” can be used interchangeably and refer to a SOC cell comprising an LSM electrode that comprises an oxygen electrode that comprises a PrOₓ coating, such that the PrOₓ coating is provided via ALD methods and/or dip coating methods. In some instances, the disclosed cell with coated oxygen electrode is a SOC cell comprising a La₁₋ₓSrₓMnO₃ (LSM) oxygen electrode coating with a disclosed PrOₓ coating. In some instances, the disclosed cell with coated oxygen electrode is a a fuel-supported solid oxide button cell. fuel-supported cell is comprised of Ni/YSZ-YSZ-LSM/SSZ comprising an LSM oxygen electrode comprising a PrOₓ coating.

As used herein, “LSM cell”, “baseline, uncoated LSM cell”, “uncoated, baselined LSM cell”, “baseline, uncoated cell”, and “uncoated, baselined cell” can be used interchangeably, and refer to a SOC cell comprising an LSM electrode. In some instances, the baseline, uncoated LSM cell is a SOC cell comprising a La₁₋ₓSrₓMnO₃ (LSM) oxygen electrode. In some instances, the baseline, uncoated LSM cell is a fuel-supported solid oxide button cell. Fuel-supported cell is comprised of Ni/YSZ-YSZ-LSM/SSZ.

As used herein, the terms “optional” or “optionally” means that the subsequently described event or circumstance can or cannot occur, and that the description includes instances where said event or circumstance occurs and instances where it does not.

Unless otherwise specified, temperatures referred to herein are based on atmospheric pressure (i.e., one atmosphere).

The following abbreviations are used herein throughout and can be used interchangeably with the corresponding text phrase.

| Abbreviation | Meaning |
|---|---|
| ALD | Atomic layer deposition |
| HRTEM | High-resolution transmission electron microscopy |
| LSCF | Lanthanum strontium cobalt ferrite |
| LSM | LaₓSr₁₋ₓMn_{y}O_{3-δ}, e.g., as in LaₓSr₁₋ₓMn_{y}O_{3-δ} (LSM)/Sc |
| | stabilized Zirconia (SSZ) oxygen electrodes |
| ORR | Oxygen reduction reaction |
| Rₛ | Ohmic resistance |
| Rₚ | Polarization resistance |
| SDC | Samaria-Doped Ceria, e.g., as in a Sm₂O₃-doped CeO₂ |
| | electrode |
| SOC | Solid oxide cell |
| SOEC | Solid oxide electrolysis cell |
| SOFC | Solid oxide fuel cell |
| SSZ | Sc stabilized zirconia, e.g., as in a SSZ electrode. |
| TEM | Transmission electron microscopy |
| YSZ | Ni/yttria-stabilized zirconia (YSZ), e.g., as in a YSZ fuel |
| | electrode |

### B. COATED ELECTRODES

In one aspect, the disclosure relates to cells comprising a coated electrode comprising a PrOₓ layer on at least one electrode, e.g., an oxygen electrode. The disclosed electrodes can be used in a variety of SOCs, including SOECs and/or SOFCs.

The disclosed coated electrodes provide an enhanced electrode, e.g., an oxygen electrode based on LSM and LSCF, that utilize any electrode material that is modified to increase the ionic conductivity and electrocatalytic activities, thereby improving promise to the performance and durability of the electrode. Electrochemical reactions take place on the internal surface of the electrode, and further modification and nanostructure engineering of the electrochemical reaction sites and the internal surface of the electrode, as disclosed herein, provides a very feasible approach for improving the performance of the well-developed or conventional electrodes. In various aspects, the disclosed coated electrode comprises an electrode having an internal surface engineered to be porous for accessing the reactant gas, that provides an additional design space the disclosed coatings. The electrodes can be in place in an already fabricated SOC, thereby allowing for improved performance and the stability of the as-made cells.

In various aspects, the PrOₓ electrode coating can comprise a PrOₓ layer, e.g., a layer deposited by the disclosed ALD methods for providing a PrOₓ layer, that is from about 5 nm to about 50 nm. In a still further aspect, the PrOₓ oxygen electrode coating can comprise multiple layers wherein each layer is deposited by the disclosed ALD methods for providing a PrOₓ layer. In a yet further aspect, the PrOₓ coating comprises a plurality of PrOₓ layers, e.g., from 1 to 10 PrOₓ layers individually provided by the disclosed ALD methods for providing a PrOₓ layer. In an even further aspect, the electrode is an oxygen electrode. In a still further aspect, the electrode is a LaₓSr₁₋ₓMn_{y}O_{3-δ} (LSM)/Sc stabilized Zirconia (SSZ) oxygen electrode.

In various aspects, the PrOₓ oxygen electrode coating can further comprise CoOₓ and/or MnOₓ. In a further aspect, the PrOₓ oxygen electrode coating can comprise a PrOₓ layer that is co-deposited with CoOₓ and/or MnOₓ as the PrOₓ layer is deposited thereby providing a layer that is a mixture of PrOₓ with CoOₓ and/or MnOₓ. In a still further aspect, the PrOₓ oxygen electrode coating can comprise a PrOₓ layer, e.g., a layer deposited by the disclosed ALD methods for providing a PrOₓ layer, that is overcoated in a subsequent step by a CoOₓ layer or a MnOₓ layer, e.g., a layer deposited by the disclosed ALD methods for providing a CoOₓ and/or MnOₓ layer.

In various aspects, the disclosed coated electrodes comprise a dual layer comprising CeOₓ/PrOₓ. In a further aspect, a disclosed electrode comprising a dual layer comprising CeOₓ/PrOₓ comprises a subjacent CeOₓ layer and superjacent PrOₓ layer, wherein the use of subjacent and superjacent refer to the relative positioning of each layer relative to one another and the layer most exterior to the backbone. In a still further aspect, a disclosed electrode comprising a dual layer comprising CeOₓ/PrOₓ comprises a superjacent CeOₓ layer and subjacent PrOₓ layer. In a yet further aspect, disclosed coated electrodes comprising a dual layer comprising CeOₓ/PrOₓ are useful when utilized in conjunction with a LSM/YSZ and LSCF/SDC backbone.

In a further aspect, a disclosed coated electrode can comprise multilayers, e.g., but not limited to, such as CeOₓ/PrOₓ/CeOₓ, PrOₓ/CeOₓ/PrOₓ, CeOₓ/PrOₓ/CeOₓ/PrOₓ, and PrOₓ/CeOₓ/PrOₓ/CeOₓ. In a still further aspect, individual layering of a multilayer structure can comprise CeOₓ, PrOₓ, MnOₓ, and CoOₓ, such that the number of layers, layer thickness, and layer chemistry is variable and tunable.

### C. METHODS OF MAKING DISCLOSED COATED ELECTRODES

In various aspects, the present disclosure relates to methods of making the disclosed coated electrodes. In a further aspect, the disclosed methods of making the disclosed coated electrodes comprise providing a coating comprising a PrOₓ layer onto an electrode, wherein the providing comprisings subjecting the electrode to atomic layer deposition of PrOₓ.

ALD is a chemical vapor deposition technique that sequentially applies atomic mono-layers to a substrate, typically alternating compounds, to produce a locally balanced atomic distribution of the target material (Ref. 6). ALD is uniquely suitable for depositing uniform and conformal films on complex three-dimensional topographies with high aspect ratios (Refs. 7-10). The indifference of ALD to substrate shape makes it particularly promising for applications to SOFCs, which possess a porous active structure with complex three-dimensional topographies, and with electrode performance strictly depending on the surface properties.

### D. SOCS COMPRISING DISCLOSED COATED ELECTRODES

In various aspects, the present disclosure relates to SOCs, e.g., a SOEC or a SOFC, comprising a disclosed coated electrode.

A robust SOC, e.g., a robust SOEC, subjected to electrochemical operations at elevated temperatures over the long term requires an electrode possessing high structure stability and chemical compatibility among cell components, as well as satisfying strict physical property requirements, including sufficient electrical and ionic conductivity and high catalytic activity. Heretofore, the application of new electrode materials to the cells for practical applications is faced with multiple and/or difficult challenges. The disclosed coated electrodes provide an electrode that can provide for a robust, improved SOC.

In various aspects, a disclosed SOC cell comprises a disclosed electrode. In a further aspect, the coated electrode is a coated oxygen electrode. In a further aspect, the coated oxygen electrode can comprise an LSM/SSZ oxygen electrode.

In a further aspect, the SOC cell can be a SOFC and/or SOEC, or operable as a SOFC and/or SOEC. In a yet further aspect, the SOC can comprise a Ni/yttria-stabilized zirconia (YSZ) fuel electrode and a LaₓSr₁₋ₓMn_{y}O_{3-δ} (LSM)/Sc stabilized Zirconia (SSZ) oxygen electrode. In an even further aspect, the SOC cell can comprise a La₁₋ₓSrₓMnO₃ (LSM) fuel-supported solid oxide button cell. In a further aspect, the PrOₓ coating is conformal with the underlying LSM oxygen electrode structure.

Commercial SOFCs are widely recognized for experiencing severe delamination and present rapid degradation and catastrophic failure under the electrolysis mode. The disclosed SOCs, such as a SOFC, comprising the disclosed electrodes, i.e., an electrode, such as an oxygen electrode, comprising a coating comprising a PrOₓ layer, wherein the PrOₓ layer is deposited by the disclosed ALD methods, is rendered ready for hydrogen production with superior stability and about three times the hydrogen production rate of the state-of-the-art commercial cells. In various aspects, the disclosed coated electrode can further comprise a CoOₓ and/or MnOₓ layer into electrode coating, e.g., a multilayer ALD coating, in order to provide enhanced tolerance of Cr-contamination in SOCs.

### E. REFERENCES

References are cited herein throughout using the format of reference number(s) enclosed by parentheses corresponding to one or more of the following numbered references. For example, the citation of references numbers 1 and 2 immediately herein below would be indicated in the disclosure as (Refs. 1 and 2).
Ref 1. Ebbesen SD, Jensen SH, Hauch A, Mogensen MB. High temperature electrolysis in alkaline cells, solid proton conducting cells, and solid oxide cells. Chemical reviews. 2014; 114 (21): 10697-734.
Ref 2. Schefold J, Brisse A, Poepke H. 23,000 h steam electrolysis with an electrolyte supported solid oxide cell. International Journal of Hydrogen Energy. 2017; 42 (19): 13415-26.
Ref 3. Minh NQ. Ceramic Fuel Cells. Journal of the American Ceramic Society. 1993; 76 (3): 563-88.
Ref 4. Hernandez E, Baiutti F, Morata A, Torrell M, Tarancón A. Infiltrated mesoporous oxygen electrodes for high temperature co-electrolysis of H2O and CO2 in solid oxide electrolysis cells. Journal of Materials Chemistry A. 2018; 6 (20): 9699-707.
Ref 5. Virkar AV, Lim H-T, Tao G. Failure of solid oxide fuel cells by electrochemically induced pressure. Procedia IUTAM. 2014; 10:328-37.
Ref 6. MIIKKULAINEN, V., LESKELA, M., RITALA, M. & PUURUNEN, R. L. 2013. Crystallinity of inorganic films grown by atomic layer deposition: Overview and general trends. Journal of Applied Physics, 113. 021301.
Ref 7. GONG, Y., PATEL, R. L., LIANG, X., PALACIO, D., SONG, X., GOODENOUGH, J. B. & HUANG, K. 2013. Atomic Layer Deposition Functionalized Composite SOFC Oxygen electrode La_{0.6}Sr_{0.4}Fe_{0.8}Co_{0.2}O_{3-δ}—Gd_{0.2}Ce_{0.8}O_{1.9}: Enhanced Long-Term Stability. Chemistry of Materials, 25, 4224-4231.
Ref 8. GONG, Y., PALACIO, D., SONG, X., PATEL, R. L., LIANG, X., ZHAO, X., GOODENOUGH, J. B. & HUANG, K. 2013. Stabilizing Nanostructured Solid Oxide Fuel Cell Oxygen electrode with Atomic Layer Deposition. Nano Letters, 13, 4340-4345.
Ref 9. KÜNGAS, R., YU, A. S., LEVINE, J., VOHS, J. M. & GORTE, R. J. 2013. An Investigation of Oxygen Reduction Kinetics in LSF Electrodes. Journal of The Electrochemical Society, 160, F205-F211.
Ref 10. YU, A. S., KÜNGAS, R., VOHS, J. M. & GORTE, R. J. 2013. Modification of SOFC Oxygen electrodes by Atomic Layer Deposition. Journal of The Electrochemical Society, 160, F1225-F1231.
Ref 11. Hauch, Anne, R Kungas, P Blennow, A B Hansen, J B Hansen, B V Mathiesen and Mogens Bjerg Mogensen. “Recent Advances in Solid Oxide Cell Technology for Electrolysis.” Science 370, no. 6513 (2020).
Ref 12. Dr. Sunita Satyapal, Director, U.S. Department of Energy Hydrogen and Fuel Cell Technologies Office, 2021 AMR Session; Plenary https://www.energy.gov/sites/default/files/20221-06/hfto-amr-plenary-satyapal-2021.pdf
Ref 13. Badwal, S.; Deller, R.; Foger, K.; Ramprakash, Y.; Zhang, J., Interaction between chromia forming alloy interconnects and air electrode of solid oxide fuel cells. Solid State Ionics 1997, 99 (3-4), 297-310.
Ref 14. Chen, X.; Zhen, Y.; Li, J.; Jiang, S. P., Chromium deposition and poisoning in dry and humidified air at (La0. 8Sr0. 2) 0.9 MnO3+δoxygen electrodes of solid oxide fuel cells. international journal of hydrogen energy 2010, 35 (6), 2477-2485.
Ref 15. Jiang, S. P.; Chen, X., Chromium deposition and poisoning of oxygen electrodes of solid oxide fuel cells—a review. International Journal of Hydrogen Energy 2014, 39 (1), 505-531.
Ref 16 Park, E.; Taniguchi, S.; Daio, T.; Chou, J. T.; Sasaki, K., Influence of oxygen electrode polarization on the chromium deposition near the oxygen electrode/electrolyte interface of SOFC. International Journal of Hydrogen Energy 2014, 39 (3), 1463-1475.
Ref 17. S. P. Jiang, X. Chen, International Journal of Hydrogen Energy, 39 (2014) 505-531.

### F. ASPECTS

The following listing of exemplary aspects supports and is supported by the disclosure provided herein.
Aspect 1. An electrode comprising: an electrode and an electrode coating layer; wherein the electrode coating layer comprises a conformal nanolayer comprising a PrOₓ layer on the electrode.
Aspect 2. The electrode of claim 1, wherein the PrOₓ layer comprises Pr₆O₁₁, Pr₁₁O₂₀, Pr₅O₉, or combinations thereof.
Aspect 3. The electrode of claim Aspect 2, wherein the PrOₓ layer comprises Pr₆O₁₁.
Aspect 4. The electrode of any one of Aspect 1-Aspect 3, wherein the electrode comprises an LSCF electrode.
Aspect 5. The electrode of any one of Aspect 1-Aspect 3, wherein the electrode comprises an oxygen electrode.
Aspect 6. The electrode of claim Aspect 5, wherein the electrode comprises an LSM/SSZ oxygen electrode.
Aspect 7. The electrode of claim Aspect 5, wherein the LSM/SSZ oxygen electrode comprises LaₓSr₁₋ₓMn_{y}O_{3-δ}.
Aspect 8. The electrode of any one of Aspect 1-Aspect 7, wherein the PrOₓ layer comprises one PrOₓ layer.
Aspect 9. The electrode of claim Aspect 8, wherein the PrOₓ layer has a thickness of about from about 1 nm to about 200 nm.
Aspect 10. The electrode of claim Aspect 8, wherein the PrOₓ layer has a thickness from about 1 nm to about 100 nm.
Aspect 11. The electrode of claim Aspect 8, wherein the PrOₓ layer has a thickness from about 1 nm to about 80 nm.
Aspect 12. The electrode of claim Aspect 8, wherein the PrOₓ layer has a thickness from about 1 nm to about 60 nm.
Aspect 13. The electrode of claim Aspect 8, wherein the PrOₓ layer has a thickness from about 1 nm to about 40 nm.
Aspect 14. The electrode of claim Aspect 8, wherein the PrOₓ layer has a thickness from about 1 nm to about 20 nm.
Aspect 15. The electrode of claim Aspect 8, wherein the PrOₓ layer has a thickness from about 2 nm to about 100 nm.
Aspect 16. The electrode of claim Aspect 8, wherein the PrOₓ layer has a thickness from about 2 nm to about 80 nm.
Aspect 17. The electrode of claim Aspect 8, wherein the PrOₓ layer has a thickness from about 2 nm to about 60 nm.
Aspect 18. The electrode of claim Aspect 8, wherein the PrOₓ layer has a thickness from about 2 nm to about 40 nm.
Aspect 19. The electrode of claim Aspect 8, wherein the PrOₓ layer has a thickness from about 2 nm to about 20 nm.
Aspect 20. The electrode of claim Aspect 24, wherein each of the plurality of PrOₓ layers has a thickness from about 2 nm to about 15 nm.
Aspect 21. The solid oxide cell of claim Aspect 8, wherein the PrOₓ layer has a thickness from about 2 nm to about 10 nm.
Aspect 22. The electrode of claim Aspect 8, wherein the PrOₓ layer has a thickness from about 5 nm to about 15 nm.
Aspect 23. The electrode of claim Aspect 8, wherein the PrOₓ layer has a thickness from about 5 nm to about 20 nm.
Aspect 24. The electrode of any one of Aspect 1-Aspect 23, wherein the PrOₓ layer comprises a plurality of PrOₓ layers.
Aspect 25. The electrode of claim Aspect 24, wherein each of the plurality of PrOₓ layers has a thickness of about from about 1 nm to about 200 nm.
Aspect 26. The electrode of claim Aspect 24, wherein each of the plurality of PrOₓ layers has a thickness from about 1 nm to about 100 nm.
Aspect 27. The electrode of claim Aspect 24, wherein each of the plurality of PrOₓ layers has a thickness from about 1 nm to about 80 nm.
Aspect 28. The electrode of claim Aspect 24, wherein each of the plurality of PrOₓ layers has a thickness from about 1 nm to about 60 nm.
Aspect 29. The electrode of claim Aspect 24, wherein each of the plurality of PrOₓ layers has a thickness from about 1 nm to about 40 nm.
Aspect 30. The electrode of claim Aspect 24, wherein each of the plurality of PrOₓ layers has a thickness from about 1 nm to about 20 nm.
Aspect 31. The electrode of claim Aspect 24, wherein each of the plurality of PrOₓ layers has a thickness from about 2 nm to about 100 nm.
Aspect 32. The electrode of claim Aspect 24, wherein each of the plurality of PrOₓ layers has a thickness from about 2 nm to about 80 nm.
Aspect 33. The electrode of claim Aspect 24, wherein each of the plurality of PrOₓ layers has a thickness from about 2 nm to about 60 nm.
Aspect 34. The solid oxide cell of claim Aspect 24, wherein each of the plurality of PrOₓ layers has a thickness from about 2 nm to about 40 nm.
Aspect 35. The electrode of claim Aspect 24, wherein each of the plurality of PrOₓ layers has a thickness from about 2 nm to about 20 nm.
Aspect 36. The electrode of claim Aspect 24, wherein each of the plurality of PrOₓ layers has a thickness from about 2 nm to about 15 nm.
Aspect 37. The electrode of claim Aspect 24, wherein each of the plurality of PrOₓ layers has a thickness from about 2 nm to about 10 nm.
Aspect 38. The electrode of claim Aspect 24, wherein each of the plurality of PrOₓ layers has a thickness from about 5 nm to about 15 nm.
Aspect 39. The electrode of claim Aspect 24, wherein each of the plurality of PrOₓ layers has a thickness from about 5 nm to about 20 nm.
Aspect 40. The electrode of any one of Aspect 1-Aspect 39, wherein the electrode coating further comprises one or more additional layer material.
Aspect 41. The electrode of claim Aspect 40, wherein the one or more additional layer material comprises ZrOₓ and/or CeOₓ.
Aspect 42. The electrode of claim Aspect 41, wherein the one or more additional layer material comprising ZrOₓ and/or CeOₓ comprises one or more ZrOₓ layer and/or one or more CeOₓ layer.
Aspect 43. The electrode of claim Aspect 40, wherein the one or more additional layer material comprises Ag, Au, and/or Pt.
Aspect 44. The electrode of claim Aspect 43, wherein one or more additional layer material comprising Ag, Au, and/or Pt comprises one or more Ag layer, one or more Au layer, and/or one or more Pt layer.
Aspect 45. The electrode of claim Aspect 40, wherein the one or more additional layer material comprises CoOₓ and/or MnOₓ.
Aspect 46. The electrode of claim Aspect 45, wherein the one or more additional layer material comprising CoOₓ and/or MnOₓ comprises one or more CoOₓ layer and/or one or more MnOₓ layer.
Aspect 47. The electrode of claim Aspect 45, wherein the electrode coating further comprising CoOₓ and/or MnOₓ comprises one or more CoOₓ layer and/or one or more MnOₓ layer deposited onto a PrOₓ layer.
Aspect 48. The electrode of claim Aspect 45, wherein the electrode coating further comprising CoOₓ and/or MnOₓ comprises a layer comprising a mixture of PrOₓ and CoOₓ and/or MnOₓ.
Aspect 49. The electrode of claim Aspect 48, wherein the layer comprising a mixture of PrOₓ and CoOₓ and/or MnOₓ is a co-deposited layer of PrOₓ and CoOₓ and/or MnOₓ.
Aspect 50. The electrode of any one of Aspect 40-Aspect 49, wherein the one or more additional layer material has a thickness from about 1 nm to about 200 nm.
Aspect 51. A solid oxide cell comprising the electrode of any one of Aspect 1-Aspect 50.
Aspect 52. The solid oxide cell of claim Aspect 51, wherein the solid oxide cell is a SOFC.
Aspect 53. The solid oxide cell of claim Aspect 51, wherein the solid oxide cell is a SOEC.
Aspect 54. The solid oxide cell of any one of Aspect 51-Aspect 53, wherein the solid oxide cell comprises a NiO/YSZ fuel cell.
Aspect 55. The solid oxide cell of any one of Aspect 51-Aspect 53, wherein the solid oxide cell comprises a Ni/YSZ-YSZ-LSM/SSZ cell.
Aspect 56. An article comprising the solid oxide cell of any one of Aspect 51-Aspect 55.
Aspect 57. The article of claim Aspect 56, wherein the article comprises a stack of solid oxide cells; and wherein the stack of solid oxide cells comprises individual solid oxide cells interconnected to one another.
Aspect 58. A method of making an electrode of any one of Aspect 1-Aspect 49, the method comprising: providing a substrate an atomic layer deposition reaction chamber; performing at least one atomic layer deposition cycle to form an electrode coating layer on a surface of an electrode; wherein the electrode coating layer comprises PrOₓ; wherein the first coating layer is superjacent to the substrate.
Aspect 59. The method of claim Aspect 58, wherein performing an atomic layer deposition cycle to form a electrode coating layer comprises passing a precursor and an oxidant into the atomic deposition layer reaction chamber.
Aspect 60. The method of claim Aspect 59, wherein the precursor comprises (C3H7C5H4)3Pr; and wherein the oxidant comprises ozone.
Aspect 61. The method of any one of Aspect 58-Aspect 60, wherein the electrode is an oxygen electrode.
Aspect 62. The method of any one of Aspect 58-Aspect 61, wherein atomic layer deposition reaction chamber has a temperature from about 100° C. to about 500° C.
Aspect 63. The method of claim Aspect 62, wherein atomic layer deposition reaction chamber has a temperature from about 250° C. to about 350° C.
Aspect 64. The method of claim Aspect 63, wherein atomic layer deposition reaction chamber has a temperature from about 280° C. to about 320° C.
Aspect 65. The method of any one of Aspect 58-Aspect 64, wherein the least one atomic layer deposition cycle to form a first coating layer for a period from about 1 minute to about 20 minutes per cycle.
Aspect 66. The method of claim Aspect 65, wherein the least one atomic layer deposition cycle to form a first coating layer is from 1 to 50 cycles.
Aspect 67. A method of carrying out electrolysis, the method comprising providing an SOEC cell comprising the electrode of any one of Aspect 1-Aspect 49, and carrying out electrolysis with same.
Aspect 68. The method of claim Aspect 67, wherein the SOEC cell is a plurality of SOEC cells forming an SOEC stack.

From the foregoing, it will be seen that aspects herein are well adapted to attain all the ends and objects hereinabove set forth together with other advantages which are obvious and which are inherent to the structure.

While specific elements and steps are discussed in connection to one another, it is understood that any element and/or steps provided herein are contemplated as being combinable with any other elements and/or steps regardless of an explicit provision of the same while still being within the scope provided herein.

It will be understood that certain features and subcombinations are of utility and may be employed without reference to other features and subcombinations. This is contemplated by and is within the scope of the claims.

Since many possible aspects may be made without departing from the scope thereof, it is to be understood that all matter herein set forth or shown in the accompanying drawings and detailed description is to be interpreted as illustrative and not in a limiting sense.

It is also to be understood that the terminology used herein is for the purpose of describing particular aspects only, and is not intended to be limiting. The skilled artisan will recognize many variants and adaptations of the aspects described herein. These variants and adaptations are intended to be included in the teachings of this disclosure and to be encompassed by the claims herein.

Now having described the aspects of the present disclosure, in general, the following Examples describe some additional aspects of the present disclosure. While aspects of the present disclosure are described in connection with the following examples and the corresponding text and figures, there is no intent to limit aspects of the present disclosure to this description. On the contrary, the intent is to cover all alternatives, modifications, and equivalents included within the spirit and scope of the present disclosure.

### G. EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### 1. Experimental Methods

A La₁₋ₓSrₓMnO₃ (LSM) fuel-supported solid oxide button cell coated with PrOₓ via ALD was employed for the experiments described herein. The experimental results for the LSM baseline cell, i.e., the same LSM cell but without PrOₓ coating, were included for comparison purposes. The oxygen electrode can limit the active area of the cells; as such, both the power density and current density are calculated considering this area even if the fuel electrode exposure to fuel is larger in area than the active area of the oxygen electrode.

ALD coating was performed in a commercial GEMStar-8 ALD reactor from Arradiance Inc. Tris(i-propylcyclopentadienyl) praseodymium (99.9%-Pr; chemical formula (C₃H₇C₅H₄)₃Pr) was utilized as a precursor while ozone was comprised the oxidizing agent during ALD deposition. Desired cycles were performed for deposition of PrOₓ, leading to an ALD coating of the oxygen electrode backbone. In the examples below, ALD was carried out at 200-300° C. about 300 cycles. PrOₓ deposition can be controlled, e.g., temperature and number of cycles, to achieve the optimal or the desired ALD layer thickness. No masking or specific treatment was applied to the NiO/YSZ anode before ALD processing. Without wishing to be bound by a particular theory, it is believed that the thick and very dense NiO/YSZ anode prevented precursor penetration during the ALD processing, and according, the impact of ALD coating on the Ni/YSZ anode appeared to be negligible. No surface pretreatment or heat-treatment was applied before or after ALD coating either. The cell electrochemical operation was carried out directly after the ALD coating.

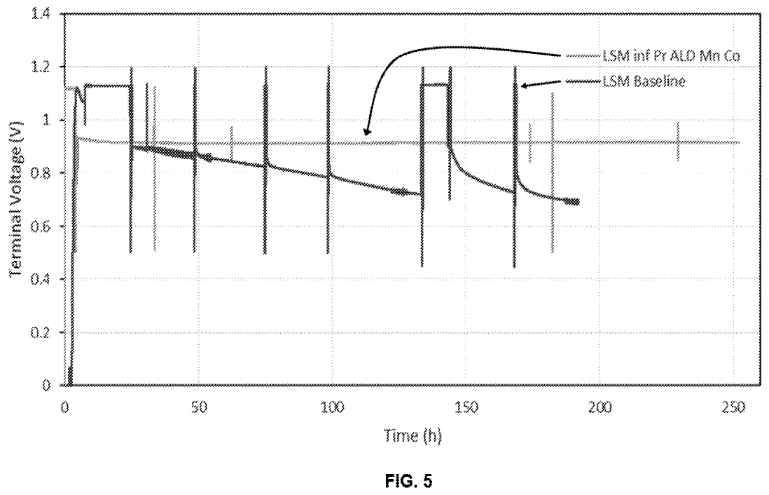

In some instances, e.g., such as in used for the experiment described in FIG. 5, a cell, such as an LSM cell, were dip-coated, followed by ALD deposition. Briefly, an LSM cell was infiltrated by a dip coating procedure using a precursor solution comprising Pr(NO₃) 3-6H₂O at a solution concentration of 0.75 M of precursor and 1.0 M of CA-H₂O. The ultrasonically dispersed solution was then used to coat for 10 min the LSM modified cell, followed by firing at 500-800° C. Subsequently, Mn and Co were deposited using ALD deposition as described herein using a GEMStar-8 ALD reactor (Arradiance Inc., Sudbury, Massachussetts).

All cell tests were performed on a test stand. The platinum mesh was used for fuel and oxygen electrode lead connections. The fuel and air stream flow rates were controlled separately using mass flow controllers. Before any electrochemical measurements, both cells were current-treated under a small current density of about 0.1 A/cm² to ensure they were activated. The cell performance was examined using a TrueData-Load Modular Electronic DC Load, which provides voltage and current accuracies of 0.03% FS of the range selected+/−0.05% of the value. The cell impedance spectra were examined using a potentiostat/galvanostat (Solartron 1287A) equipped with a frequency response analyzer (Solartron 1260). Impedance measurements were carried out using a Solatron 1260 frequency response analyzer in a frequency range from 50 mHz to 100 KHz. The impedance spectra and resistance (ohmic resistance Rₛ and polarization resistance Rₚ) presented are those measured under a DC bias current of 0.3 A/cm². On a Nyquist plot, Rₛ was determined by the intercept at the higher frequency end, and Rₚ was determined by the distance between two intercepts. The electrochemical operation of the LSM cell coated with Pr was analyzed in SOFC (solid oxide fuel cell) and SOEC (solid oxide electrolysis cell) modes to quantify the performance and reversibility of the cell at high temperatures (650-850° C.).

Transmission electron microscopy (TEM) samples were prepared by mechanically polishing and subsequent ion milling in a liquid-nitrogen cooled holder. Electron diffraction, diffraction contrast, and high-resolution TEM imaging were performed in a JEOL JEM-2100 operated at 200 kV.

### 2. Disclosed Cell with a Conformal ALD Layer on an Internal Surface of a Porous Electrode

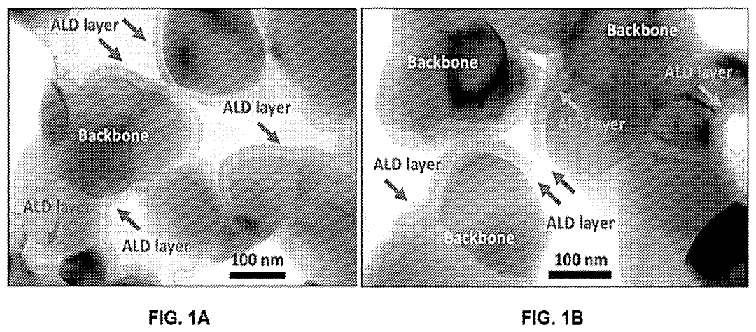

The ALD processing disclosed herein provided a uniform and conformal ALD layer appeared to be deeply covering the narrow gap of ˜20 nm of the original porous electrode, as shown in FIGS. 1A-1B. TEM images show the deep penetration of the ALD vapor into the narrow gap of the porous electrode from the as-received cells. The ALD layer is entirely uniform and conformal, and subsequent formation of the conformal and stable nanostructure on the internal surface of the anode upon cell operation.

### 3. SOFC Operation of a Disclosed Cell with an LSM Oxygen Electrode with an ALD Pr Coating

Coated and uncoated LSM cells used herein had an active area of 2 cm², and both analyzed cells were from the same cell batch and had nearly identical initial performance. The fuel-supported cell comprised Ni/YSZ-YSZ-LSM/SSZ. The electrochemical operation was examined at 700° C., 750° C., 800° C., and 850° C. for a disclosed LSM cell comprising an oxygen electrode coated with PrOₓ via ALD (also referred to herein throughout as a “disclosed LSM with PrOₓ coated oxygen electrode”) and the baseline, uncoated LSM cell are shown in Table 1, which shows data obtained from the I-V-P curves at 700° C., 750° C., 800° C., and 850° C. for the baseline, uncoated LSM cell and disclosed LSM with PrOₓ coated oxygen electrode.

TABLE 1

ALD coated cell,
commercial button cell,

| | |
|---|---|
| Ni/YSZ-YSZ-LSM/SSZ | Baseline cell, |
| No precious metal | commercial button cell |
| inside the ALD layer | Ni/YSZ-YSZ-LSM/SSZ |

| Operation | Peak power | Operation | Peak power |
|---|---|---|---|
| time & | density, | time & | density, |
| temperature | W/cm² | temperature | W/cm² |
| 0 hr 700° C. | 0.986 | 7 hr 700° C. | 0.398 |
| 0 hr 750° C. | 1.653 | 0 hr 750° C. | 0.627 |
| 0 hr 800° C. | 1.901 | 0 hr 800° C. | 0.969 |
| 0 hr 850° C. | 2.139 | 1 hr 850° C. | 1.231 |

| ALD coated cell, | | |
|---|---|---|
| commercial button cell, | | |
| Ni/YSZ-YSZ-LSM/SSZ | | |
| No precious metal | | |
| inside the ALD layer | | Peak Power Density |
| Operation | Peak power | of ALD coated cell |
| time & | density, | comparing with |
| temperature | W/cm² | baseline |
| 0 hr 700° C. | 0.986 | 248% |
| 0 hr 750° C. | 1.653 | 264% |
| 0 hr 800° C. | 1.901 | 196% |
| 0 hr 850° C. | 2.139 | 174% |

A baseline LSM, i.e., lacking the disclosed LSM oxygen electrode comprising an ALD PrOₓ coating, achieved a maximum peak power density of 0.398, 0.627, 0.969, and 1.231 W/cm² at 700° C., 750° C., 800° C., and 850° C., respectively. On the other hand, a disclosed LSM with PrOₓ coated oxygen electrode achieved a maximum peak power density of 0.986, 1.653, 1.901, and 2.139 W/cm² at 700° C., 750° C., 800° C., and 850° C., respectively. The performance for the ALD-coated cell under SOFC operation represents an improvement of 248%, 264%, 196%, and 174% compared to the uncoated LSM cell. Moreover, the data in Table 1 demonstrates the electrochemical performance of the disclosed LSM with PrOₓ coated oxygen electrode compared to a baseline, uncoated cell at different operation temperatures. The improvement of the disclosed LSM with PrOₓ coated oxygen electrode is noticeable beneficial even at low temperatures, e.g., the performance of 0.986 W/cm² at 700° C. is a higher absolute value than that of the uncoated LSM cell at 800° C., which is also similar to the compared performance for the disclosed LSM with PrOₓ coated oxygen electrode operated at 750° C. outperforming the uncoated LSM cell operated at 850° C. With the same desired power output, the data indicated that the disclosed method for ALD coating of an oxygen electrode with PrOₓ can significantly lower the operation temperature 100° C. in comparison to that of the LSM baseline.

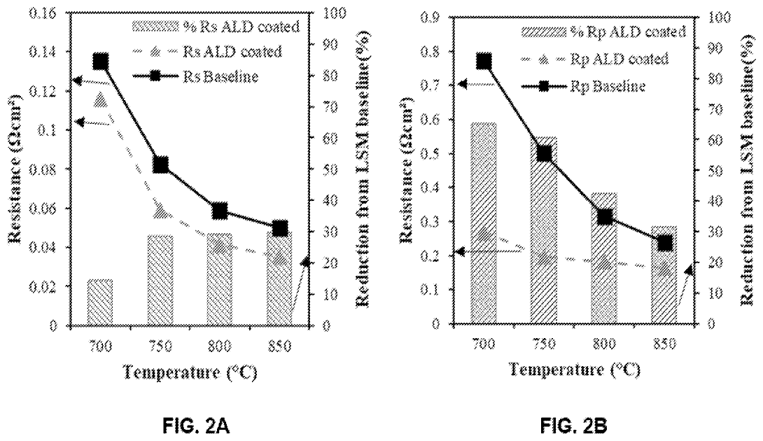

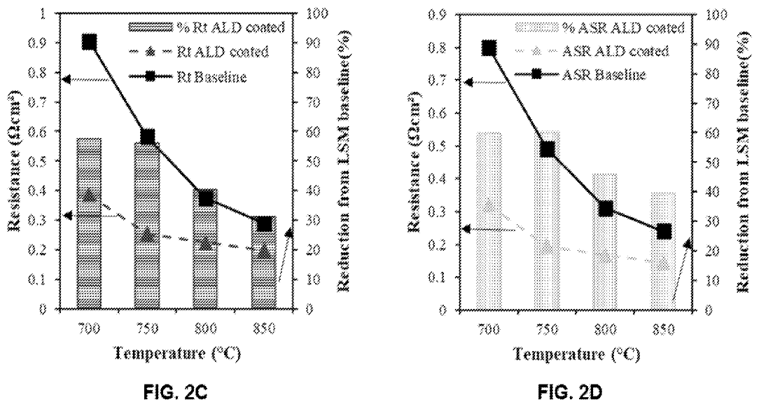

The increased cell peak power density was accompanied by the reduction of the cell area-specific resistance (ASR). FIGS. 2A-2D show ASR and ohmic resistance, Rₛ, polarization resistance, Rₚ, and total resistance, Rₜ, and the reduction (%) variation of each of that resistance as a function of temperature. The obtained values for the ASR for the disclosed LSM with PrOₓ coated oxygen electrode under SOFC operation represented a reduction of 60%, 60%, 46%, and 40% compared to the ASR values of the uncoated LSM cell (see FIG. 2D). Rₛ, Rₚ, and Rₜ values obtained from the impedance plots for the disclosed LSM with PrOₓ coated oxygen electrode and the baseline, uncoated LSM cell are shown in FIGS. 2A-2C. The overall values for the ohmic and polarization resistance show a remarkable reduction in the disclosed LSM with PrOₓ coated oxygen electrode. The Rₛ values of the coated cell was reduced by 14.3%, 28.4%, 29.2%, and 29.7% compared to the baseline, uncoated LSM/SSZ cell. Additionally, the Rₚ values of the disclosed LSM with PrOₓ coated oxygen electrode were reduced by 65%, 61%, 42%, and 32% compared to the baseline, uncoated LSM/SSZ cell. The overall Rₜ values are significantly reduced by 57.6%, 56.1%, 40.3%, and 31.2% compared to the baseline, unmodified LSM/SSZ cell. The improvement in the ohmic and polarization resistance confirmed the improved electronic and ionic conductivity of the disclosed LSM with PrOₓ coated oxygen electrode, which in turn improved the electrochemical activity of the disclosed LSM with PrOₓ coated oxygen electrode.

The plotted results in FIGS. 2A-2D show the remarkable improvement of the disclosed disclosed LSM with PrOₓ coated oxygen electrode for the SOFC operation compared to that of the uncoated, baseline LSM. The improvement in Rₚ is larger (65%) at 700° C., but diminished slightly (32%) at 850° C. On the other hand, the Rₛ value improvement is larger (29.7%) at 850° C. compared to the improvement (14.3%). The overall ASR value of the coated LSM cell maintains a reduction of ˜40% at 850° C., while a more significant ˜60% reduction is observed at 700° C. The ASR reduction is in line with the reduction for the Rₜ, with the LSM coated cell reaching a value reduction on Rₜ ˜58% at 700° C. and a slightly more modest reduction value of 31% at 850° C.

### 4. High Current Density of a Disclosed Cell with an LSM Oxygen Electrode with an ALD Pr Coating

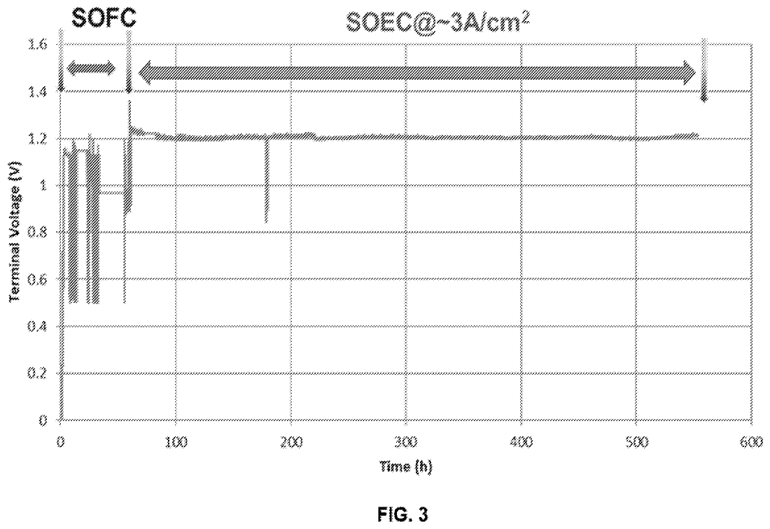

After the evaluation of the SOFC performance of the disclosed LSM with PrOₓ coated oxygen electrode at a temperature of 700-850° C., the disclosed LSM with PrOₓ coated oxygen electrode was switched to SOEC operation directly. FIG. 3 shows the evolution of the terminal voltage for the disclosed LSM with PrOₓ coated oxygen electrode. The data plotted shows the initial 50 h of operation under SOFC operation. The SOEC operation was performed under constant current at close to 2.9-2.7 A/cm² at 850° C. For the duration of the SOEC operation, the disclosed LSM with PrOₓ coated oxygen electrode achieved a low electricity consumption with a low operation voltage of ˜1.19 V with the operation at 850° C. As the data in FIG. 3 show, the disclosed LSM with PrOₓ coated oxygen electrode demonstrated superior stability without any sign of delamination and with a gradually decreased operation voltage with increasing operation time. The high hydrogen production rate of ˜2.7-2.9 A/cm² and the low voltage of the disclosed LSM with PrOₓ coated oxygen electrode demonstrated that this cell has the key characteristics desired for commercialization with a high hydrogen production rate and low energy consumption. The results highlight the advantage of the disclosed LSM with PrOₓ coated oxygen electrode over current state-of-the-art commercial cells with the high electrolysis performance of ˜1 A/cm² at ˜1.3V. In the electrolysis mode, the disclosed LSM with PrOₓ coated oxygen electrode exhibited a low operation voltage of 1.2 V and a high current density of over 2.7 A/cm², which corresponds to three times of the hydrogen production rate of state-of-the-art commercial cells with high electrolysis performance of ˜1 A/cm² at ˜1.3V. With at least three times the hydrogen production rate compared to conventional cells, the disclosed LSM with PrOₓ coated oxygen electrode, and stacks comprising same, could achieve an estimated three-fold reduction in SOEC stack and BOP cost and footprint with an additional 5% increase in DC Efficiency.

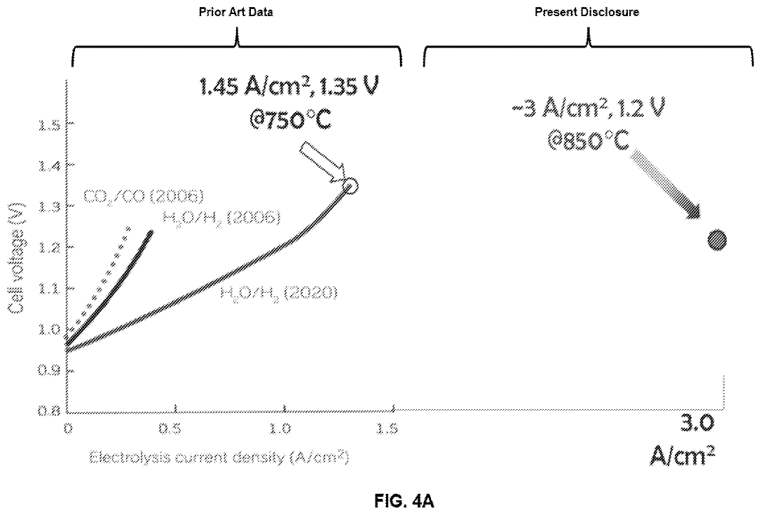

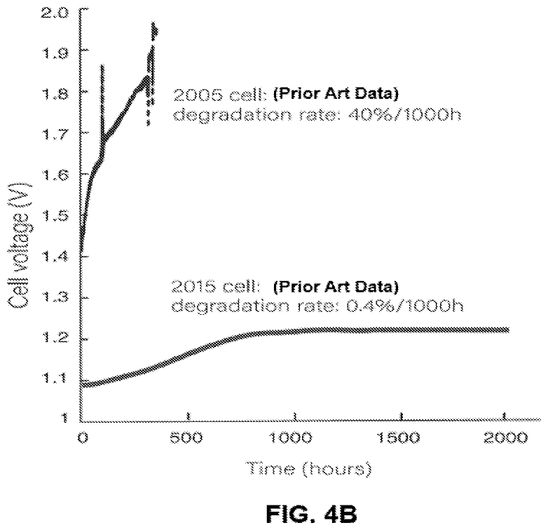

Table 2 shows the performance progression of SOEC operation for conventional oxide oxygen electrode cells. The obtained parameters for the disclosed LSM with PrOₓ coated oxygen electrode described herein have a higher operating current density and lower operating voltage than conventional cells up to 900° C. The disclosed LSM with PrOₓ coated oxygen electrode with a current density of ˜3 A/cm² and operation voltage of 1.2V outperformed the conventional cells shown for comparison in FIGS. 4A-4B (the data for conventional cells shown for comparison in FIGS. 4A-4B). Moreover, data shown herein, at the cell level outperformed the DOE 2025 SOEC target goal of 1.5 A/cm² (as described in Ref. 12).

TABLE 2

| | | Operation | | Operation | |
|---|---|---|---|---|---|
| | | current | Operation | temper- | Air |
| | | density | voltage | ature | electrode |
| Year | Author | (A/cm²) | (V) | (° C.) | materials |
| 2022 | Li | 2.23 | 1.3 | 850 | PCFC/GDC |
| 2022 | Li | 1.40 | 1.3 | 800 | PCFC/GDC |
| 2022 | Li | 0.79 | 1.3 | 750 | PCFC/GDC |
| 2021 | Wang | 1.39 | 1.3 | 850 | LCaFN-GDC |
| 2021 | Wang | 1.18 | 1.3 | 800 | LCaFN-GDC |
| 2021 | Zhao | 0.94 | 1.3 | 800 | LSM-YSZ |
| 2021 | Zhao | 1.14 | 1.3 | 800 | LSM-YSZ |
| 2021 | Zhao | 1.26 | 1.3 | 800 | LSM-YSZ |
| 2020 | Bian | 1.00 | 1.3 | 850 | LSFMo |
| 2020 | Shimada | 2.24 | 1.3 | 850 | LSM-GDC |
| 2020 | Shimada | 1.73 | 1.3 | 800 | LSM-GDC |
| 2020 | Tong | 1.07 | 1.3 | 750 | LSCF/GDC |
| 2020 | Zuo | 1.52 | 1.3 | 800 | LSF/GDC |
| 2020 | Zuo | 0.98 | 1.3 | 750 | LSF/GDC |
| 2016 | Jun | 1.31 | 1.3 | 800 | PBSCF-GDC |
| 2016 | Jun | 0.81 | 1.3 | 750 | PBSCF-GDC |
| 2016 | Myung | 2.75 | 1.3 | 900 | LSM-SSZ |
| 2016 | Myung | 0.95 | 1.3 | 800 | LSM-SSZ |
| 2016 | Tan | 1.25 | 1.3 | 800 | LSCN-GDC |
| 2014 | Fan | 1.14 | 1.3 | 800 | LSCF-YSZ |
| 2014 | Fan | 0.98 | 1.3 | 750 | LSCF-YSZ |
| 2021 | Kim | 2 | 1.8 | 800 | LSCF/GDC |
| | | | | | LSCF/GDC- |
| 2017 | Yoon | 2.1 | 1.29 | 750 | 0.55r0.5Co03-6 |
| 2015 | Mahmood | 2.2 | 1.5 | 800 | LSCF/GDC |
| | | | | | LSCF + LSCF-GDC- |
| 2014 | Lee | 1.8 | 1.3 | 750 | Sm0.5Sr0.5CoO3 |
| 2010 | Jensen | 1.8 | 1.3 | 750 | LSM-YSZ |
| 2020 | Trini | 1 | 1.25 | 800 | LSCF/CGO |

| | Fuel electrode | | |
|---|---|---|---|
| Year | materials | Electrolyte | Reference |
| 2022 | NiO/YSZ | YSZ | Journal of Power Sources 528(2022) 231202 |
| 2022 | NiO/YSZ | YSZ | Journal of Power Sources 528(2022) 231202 |
| 2022 | NiO/YSZ | YSZ | Journal of Power Sources 528(2022) 231202 |
| 2021 | Ni-YSZ | YSZ | Science China Materials 64 (2021) 1621-1631 |
| 2021 | Ni-YSZ | YSZ | Science China Materials 64 (2021) 1621-1631 |
| 2021 | Ni-YSZ | YSZ | Int. J. Hydrogen Energy 46 (2021) 25332-25340 |
| 2021 | Ni-YSZ | YSZ | Int. J. Hydrogen Energy 46 (2021) 25332-25340 |
| 2021 | Ni-YSZ | YSZ | Int. J. Hydrogen Energy 46 (2021) 25332-25340 |
| 2020 | LSFMo | LSGM | Int. J. Hydrogen Energy 45 (2021) 19813-19822 |
| 2020 | Ni-YSZ | YSZ | Ceramics International 46 (2020) 19617-19623 |
| 2020 | Ni-YSZ | YSZ | Ceramics International 46 (2020) 19617-19623 |
| 2020 | NiO/YSZ | YSZ | Journal of Power Sources 451 (2020) 227742 |
| 2020 | Ni-YSZ | YSZ | Materials 2020, 13(10), 2267 |
| 2020 | Ni-YSZ | YSZ | Materials 2020, 13(10), 2267 |
| 2016 | PBM (Co—Fe) | LSGM | Angew. Chem. Int. Ed. 2016, 55, 12512 |
| 2016 | PBM (Co—Fe) | LSGM | Angew. Chem. Int. Ed. 2016, 55, 12512 |
| 2016 | LCNT | SSZ | Nature 537 (2016) 528-531 |
| 2016 | LCNT | SSZ | Nature 537 (2016) 528-531 |
| 2016 | Ni-YSZ | YSZ | Journal of Power Sources 305 (2016) 168-174 |
| 2014 | LSCF Ni-YSZ | YSZ | Int. J. Hydrogen Energy 39 (2014) 14071-14078 |
| 2014 | LSCF Ni-YSZ | YSZ | Int. J. Hydrogen Energy 39 (2014) 14071-14078 |
| 2021 | Ni-YSZ | YSZ | Chemical Engineering Journal 410 (2021) 128318. |
| 2017 | Ni YSZ | YSZ | Nano Energy 36 (2017) 9-20 |
| 2015 | Ni-YSZ | ScSZ-GDC | Energy 90 (2015) 344-350 |
| 2014 | Ni-YSZ | YSZ | Journal of Power Sources 250 (2014) 15-20 |
| 2010 | Ni-YSZ | YSZ | Int. J. Hydrogen Energy 2010; 35: 9544-9 |
| 2020 | Ni-YSZ | YSZ | Journal of Power Sources, 450 (2020) 227599. |

### 5. Enhanced Stability of a Disclosed Cell with an LSM Oxygen Electrode with an ALD Pr Coating

Additionally, the disclosed LSM with PrOₓ coated oxygen electrode under SOEC operation, as described herein, has enhanced stability. Without wishing to be bound by a particular theory, it is believed that the enhanced stability is attributable to the Pr coating of the LSM backbone that greatly suffer under SOEC operation. In contrast to the SOFC, the SOEC degradation is operation condition dependent. Under either the galvanostatic state with constant current density or potentiostatic mode with fixed overpotential and constant voltage, the degradation mechanisms of cells vary depending on the initial performance of the cell. Such degradation can complicate the optimum operation conditions and resulted in the universal degradation that is observed in almost all SOECs, especially at the first 400-500 h of operations (shown in FIGS. 4A-4B). In contrast, the disclosed LSM with PrOₓ coated oxygen electrode as demonstrated from data shown in FIG. 3 was associated with an extraordinarily stable SOEC operation upon switching from SOFC to SOEC mode operation upon the first 500 hours operation. As described above, SOEC cells usually present either catastrophic delamination or the accelerated degradation.

### 6. Increased Durability of a Disclosed Cell with an LSM Oxygen Electrode with an ALD Pr Coating Having Cr Contamination

The disclosed LSM with PrOₓ coated oxygen electrode was also expected to increase the Cr tolerance of the cells and increase the cell durability. Cr vapor contamination arising from evaporation at the metallic interconnect, and their reactions with Sr containing perovskite are remain a severe problem for both LSM and LSCF based electrodes. Individual SOFC cells need to be connected electrically in series, to form stacks in order to generate the desired power output with high voltage using the interconnect. Thus, the interconnect materials should have high electrical conductivity and negligible ionic conductivity and be chemically and structurally stable under both air and fuel environment. There are basically two types of interconnect materials commonly used in SOFCs, including doped LaCrO₃-based ceramic materials and metallic materials.

Compared to ceramic interconnect materials, metallic materials have high electronic and thermal conductivity, negligible ionic conductivity, good machinability, and low cost. However, metal alloys of high-temperature oxidation resistance used as interconnect in SOFCs generally contain Cr as an alloying element to form a protective chromium oxide scale (Cr₂O₃). At high temperatures, volatile Cr species such as CrO₃ and Cr(OH)₂O₂ are generated over the oxide scale (Ref. 13). Volatilization of Cr species strongly depends on the oxygen partial pressure and the water content (Refs. 14-16). In the oxygen electrode end, at high temperatures, volatile Cr species such as CrO₃ and Cr(OH)₂O₂ are generated over the oxide scale in oxidizing atmospheres. Such volatile Cr species subsequently poison and react with the oxygen electrodes such as LSM and LSCF causing rapid degradation of the cell performance.

The mechanism of Cr deposition process described above implies that an electrode surface coating layer, that is inert to Cr inward diffusion to the oxygen electrode could conceivably act as a barrier layer to prevent the direct reaction between the Cr with the electrode and enhance Cr tolerance. It is worthwhile to point out that the CoOₓ will be inherently tolerant to Cr contaminants for LSCF/SDC electrodes. It is well documented that, once LSCF is exposed to Cr, Cr deposition occurs preferentially on the segregated SrO but not on Co₃O₄, and the CO₃O₄ incorporation or (MnCr)Oₓ could separate the Cr vapor from its reaction with Sr cation (Ref. 17). Such increased Cr tolerance through the incorporation (MnCr)Oₓ with PrOₓ onto the surface layer of LSM/SSZ electrode is demonstrated obtained for disclosed LSM with PrOₓ coated oxygen electrode. FIG. 5 shows the evolution of the terminal voltage comparing when the baseline and the surface-modified LSM cells are operated at a constant current density of 0.3 A/cm² in SOFC mode under Cr contamination. The data plotted for the baseline, uncoated LSM cell shows an apparent degradation in SOFC mode under Cr exposure. The voltage drop for different timeframes for the baseline, uncoated LSM cell shows values with a reduced voltage of 28 mV at 25 h (1.12 mV/h or 0.12%/h); 76 mV at 50 h (1.52 mV/h or 0.16%/h); 105 mV at 74 h (1.42 mV/h or 0.15%/h); and 181 mV at 109 h (1.66 mV/h or 0.18%/h).

The drop in voltage corresponded to a 20% reduction for the SOFC operation with exposure to a Cr source when subject to a current density of 0.3 A/cm², and this is equivalent to a 1.66 mV reduction for each hour of operation, which is equivalent to a 0.18% reduction for each hour of operation. In contrast, the data plotted for the disclosed LSM with PrOₓ coated oxygen electrode shows the voltage remains constant for the duration of the long-term operation. There is an initial drop in voltage for the first ˜27 h, but the cell performance is constant for the following 213 hours duration of the test. The change in voltage values show 15 mV at 27 h (0.55 mV/h or 0.05%/h); 14 mV at 168 h (0.08 mV/h or 0.009%/h); and 12 mV at 240 h (0.05 mV/h or 0.005%/h). Including the initial voltage drop, the overall reduction corresponds to 1.3% (˜5%/Kh) for the 240 h long-term test under Cr exposure in SOFC mode at 750° C.

In comparison with the uncoated, baseline LSM cell that exhibited fast degradation or the drop of the voltage, the disclosed LSM with PrOₓ coated oxygen electrode displayed a stable terminal voltage and increased tolerance towards Cr contamination. Based on the foregoing results, once incorporated with the Cr tolerant electrocatalytic such as CoOₓ into ALD coating, the multilayer ALD coating is expected to present superior tolerance of Cr-contaminations. Both the performance and the Cr-tolerance of the commercial cells can be further optimized upon changing the ALD layer thickness and developing the multilayers of ALD coating such as PrOₓ/CoOₓ/using the disclosed methods and compositions.

### 7. Summary

The disclosed LSM with PrOₓ coated oxygen electrode comprising, for example, an ALD coating of 20 nm thick PrOₓ, provides enhanced performance in both the fuel cell and electrolysis mode of a cell with LaₓSr₁₋ₓMn_{y}O₃-(LSM)/YSZ oxygen electrodes. In fuel cell mode, at 850° C., the uncoated, baseline LSM cells have a peak power density of 1.231 W/cm² which is the ordinary performance for conventional cells. Once the ALD coating of the conformal layer of PrOₓ was provided to a previously uncoated conventional cell, the power density increased to 2.139 W/cm², which was 174% of that of the baseline without coating. In the electrolysis mode, the baseline cells with LaₓSr₁₋ₓMn_{y}O₃-(LSM)/YSZ oxygen electrodes are known to be prone to experiencing delamination during the SOEC operation. As disclosed herein, the disclosed LSM with PrOₓ-coated oxygen electrode exhibited a low operation voltage of 1.2 V and a high current density of over 2.8 A/cm². The disclosed LSM with PrOₓ coated oxygen electrode were associated with a high electrolysis performance of ˜3A/cm² & ˜1.2V-which was three times the hydrogen production rate of conventional cells. As described above, the disclosed LSM with PrOₓ coated oxygen electrode performance is demonstrated herein to outperform the DOE 2025 SOEC target goal of 1.5 A/cm². The disclosed LSM with PrOₓ coated oxygen electrode when operated as SOEC cells also exhibited excellent stability over the first 500 hours of operation, usually the periods that exbibit the most severe degradation for the state-of-the-art commercial cells. In short, the disclosed methods and materials providing ALD coating of oxygen electrodes of conventional cells that are designed for SOFC commercial applications transform the conventional cells into high-performing SOECs. It is believed that the disclosed PrOₓ coating can further comprise a (MnCo) Oₓ ALD coating to provide a multilayer ALD coating that is expected to present superior tolerance of Cr-contaminations. Overall, the ALD coating on a surface of the electrode, e.g., an internal surface, as disclosed herein above has an a multifunction integration including: (1) dramatically increased the current operating density for the high hydrogen production rate and lower operation voltage for less electricity consumption due to the decreased electrode resistance induced by ALD coating; (2) mitigated the electrode intrinsic degradation and increasing the electrode structure durability by preventing the backbone elements surface migration and surface segregation; and (3) mitigated the electrode extrinsic degradation and increasing the electrode structure durability by sealing off contamination such as Cr for penetrating the electrode backbone. The disclosed methods and materials can provide solution to various materials challenges at the cell level and could further enable extensive and more efficient SOEC stacks and systems.

It will be apparent to those skilled in the art that various modifications and variations can be made in the present disclosure without departing from the scope or spirit of the disclosure. Other aspects of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

1. An electrode comprising:
an electrode and an electrode coating layer;
wherein the electrode coating layer comprises a conformal nanolayer comprising a PrOₓ layer on the electrode.

2. The electrode of claim 1, wherein the PrOₓ layer comprises Pr₆O₁₁, Pr₁₁O₂₀, Pr₅O₉, or combinations thereof.

3. The electrode of claim 2, wherein the PrOₓ layer comprises Pr₆O₁₁.

4. The electrode of claim 1, wherein the electrode comprises an LSCF electrode.

5. The electrode of claim 1, wherein the electrode comprises an oxygen electrode.

6. The electrode of claim 5, wherein the electrode comprises an LSM/SSZ oxygen electrode.

7. The electrode of claim 5, wherein the LSM/SSZ oxygen electrode comprises LaₓSr₁₋ₓMn_{y}O_{3-δ}.

8. The electrode of claim 1, wherein the PrOₓ layer comprises one PrOₓ layer.

9. The electrode of claim 8, wherein the PrOₓ layer has a thickness from about 1 nm to about 200 nm.

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. The electrode of claim 1, wherein the PrOₓ layer comprises a plurality of PrOₓ layers.

25. The electrode of claim 23, wherein each of the plurality of PrOₓ layers has a thickness from about 1 nm to about 200 nm.

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. The claim 1, wherein the electrode coating further comprises one or more additional layer material.

41. The electrode of claim 39, wherein the one or more additional layer material comprises ZrOₓ and/or CeOₓ.

42. (canceled)

43. The electrode of claim 39, wherein the one or more additional layer material comprises Ag, Au, and/or Pt.

44. (canceled)

45. The electrode of claim 39, wherein the one or more additional layer material comprises CoOₓ and/or MnOₓ.

46. (canceled)

47. (canceled)

48. (canceled)

49. (canceled)

50. The electrode of claim 39, wherein the one or more additional layer material has a thickness from about 1 nm to about 200 nm.

51. A solid oxide cell comprising the electrode of claim 1.

52. The solid oxide cell of claim 51, wherein the solid oxide cell is a SOFC.

53. (canceled)

54. (canceled)

55. (canceled)

56. An article comprising the solid oxide cell of claim 51.

57. (canceled)

58. A method of making an electrode of claim 1, the method comprising:
providing a substrate an atomic layer deposition reaction chamber;
performing at least one atomic layer deposition cycle to form an electrode coating layer on a surface of an electrode;
wherein the electrode coating layer comprises PrOₓ;
wherein the first coating layer is superjacent to the substrate.

59. (canceled)

60. (canceled)

61. (canceled)

62. (canceled)

63. (canceled)

64. (canceled)

65. (canceled)

66. (canceled)

67. (canceled)

68. (canceled)
